(19) United States
(12) Patent Application Publication
(10) Pub. No.: US 2025/0260381 A1
(43) Pub. Date: Aug. 14, 2025

(54) BULK ACOUSTIC WAVE DEVICE INCLUDING FRAME OUTSIDE OF ACTIVE REGION AND FLAT BOTTOM PIEZOELECTRIC LAYER

(71) Applicant: Skyworks Global Pte. Ltd., Singapore (SG)

(72) Inventors: Zongliang Cao, Irvine, CA (US); Jun Yu, Irvine, CA (US); Kwang Jae Shin, Yongin-si (KR)

(21) Appl. No.: 19/040,723

(22) Filed: Jan. 29, 2025

Related U.S. Application Data
(60) Provisional application No. 63/552,013, filed on Feb. 9, 2024.
(60) Provisional application No. 63/552,029, filed on Feb. 9, 2024.
(60) Provisional application No. 63/552,042, filed on Feb. 9, 2024.

(51) Int. Cl. H03H 9/02; H03H 3/04; H03H 9/13; H03H 9/17; H03H 9/56

(52) U.S. Cl. CPC H03H 9/02086; H03H 3/04; H03H 9/132; H03H 9/173; H03H 9/568; H03H 2003/0478

(57) ABSTRACT

Aspects of this disclosure relate to bulk acoustic wave devices that include an acoustic reflector, a frame structure over the acoustic reflector, electrodes including a first electrode and a second electrode, and a piezoelectric layer having a surface facing the acoustic reflector that is flat (a) over an entirety of the active region and (b) beyond the first electrode over the acoustic reflector, The first electrode and the second electrode overlap and are on opposing sides of the piezoelectric layer in the active region. The first electrode is positioned between the piezoelectric layer and the acoustic reflector in the active region. Related acoustic wave filters, multiplexers, radio frequency modules, radio frequency systems, wireless communication devices, methods of manufacture, and methods of filtering are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/552,013, filed Feb. 9, 2024 and titled “BULK ACOUSTIC WAVE DEVICE INCLUDING PIEZOELECTRIC LAYER WITH RECESS,” and claims the benefit of priority of U.S. Provisional Application No. 63/552,029, filed Feb. 9, 2024 and titled “METHODS OF MANUFACTURING BULK ACOUSTIC WAVE DEVICE INCLUDING PIEZOELECTRIC LAYER WITH RECESS,” and claims the benefit of priority of U.S. Provisional Application No. 63/552,042, filed Feb. 9, 2024 and titled “BULK ACOUSTIC WAVE DEVICE INCLUDING FRAME OUTSIDE OF ACTIVE REGION AND FLAT BOTTOM PIEZOELECTRIC LAYER,” the disclosures of each of which are hereby incorporated by reference in their entireties and for all purposes.

### BACKGROUND

### Technical Field

The disclosed technology relates to acoustic wave devices. Embodiments of this disclosure relate to acoustic wave devices with a piezoelectric layer having a recess.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to suppressing spurious mode(s) and increasing Q while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having an active region. The bulk acoustic wave device includes a first electrode, a second electrode, and a piezoelectric layer having a recess outside of the active region of the bulk acoustic wave device. The first electrode and the second electrode overlap and are on opposing sides of the piezoelectric layer throughout the active region.

The bulk acoustic wave device can include a raised frame structure outside of the active region. The raised frame structure can be included between the recess and the active region. Alternatively, the recess can be included between the raised frame structure and the active region. The raised frame structure can be positioned on a same side of the piezoelectric layer on opposite sides of the active region. The raised frame structure can be positioned on opposite sides of the piezoelectric layer on opposite sides of the active region.

The recess can be tapered.

The bulk acoustic wave device can include a recessed frame structure located between the active region and the recess.

The piezoelectric layer can have a first thickness in the active region and a second thickness in a recessed region corresponding to the recess. The first thickness can beg at least twice the second thickness.

The bulk acoustic wave device can include an acoustic reflector, and the recess can be over the acoustic reflector. The acoustic reflector can be an air cavity. The piezoelectric layer can be thinner outside of the active region from an edge of the active region to an edge of the acoustic reflector than in the active region on at least one side of the bulk acoustic wave device. The piezoelectric layer can have different thicknesses on opposing sides of the recess and over the acoustic reflector. The bulk acoustic wave device can include a support layer over the acoustic reflector and outside of the active region. The bulk acoustic wave device can include a raised frame structure outside of the active region and over the acoustic reflector. The piezoelectric layer can have a flat surface on a side facing the acoustic reflector, in which the flat surface is in an entirety of the active region and extends beyond the recess in a direction away from the active region. The first electrode and a dielectric layer can be positioned between the flat surface of the piezoelectric layer and the acoustic reflector. A portion of the flat surface of the piezoelectric layer can abut the acoustic reflector.

Another aspect of this disclosure is a bulk acoustic wave device having an active region. The bulk acoustic wave device includes an acoustic reflector, electrodes including a first electrode and a second electrode, a raised frame layer outside the active region of the bulk acoustic wave device and at least partly over the acoustic reflector, and a piezoelectric layer having a recess over the acoustic reflector and outside of the active region of the bulk acoustic wave device, The first electrode and the second electrode overlap and are on opposing sides of the piezoelectric layer throughout the active region.

Another aspect of this disclosure is a method of manufacturing a bulk acoustic wave device. The method includes forming a piezoelectric layer over a first electrode such that the piezoelectric layer has a recess; and depositing a second electrode over the piezoelectric layer such that the recess is outside of a region in which the first electrode and the second electrode overlap and are on opposing sides of the piezoelectric layer.

Forming the piezoelectric layer can include etching the piezoelectric layer to form the recess. Etching can remove at least 50% of a thickness of the piezoelectric layer to form the recess.

Forming the piezoelectric layer can include performing a first etch of the piezoelectric layer and a second etch of the piezoelectric layer. The first etch can form a recessed frame structure. The first etch and the second etch can together form the recess.

Forming the piezoelectric layer can include selectively forming a portion of the piezoelectric layer in at least the region in which the first electrode and the second electrode overlap and are on opposing sides of the piezoelectric layer. The method can include forming a hard mask over a recessed region corresponding to the recess prior to forming the portion of the piezoelectric layer in at least the region.

Forming the piezoelectric layer can include forming the piezoelectric layer with a recessed frame structure.

The recess can have a tapered edge.

The recess can be over an acoustic reflector after the forming the piezoelectric layer. The method can include depositing a raised frame layer. The raised frame layer can be outside of the region and at least partly over the acoustic reflector in the bulk acoustic wave device after manufacturing. The raised frame layer can extend closer to the region than the recess. Alternatively, the recess can be closer to the region than the raised frame layer. Depositing the raised frame layer can be performed after the forming the piezoelectric layer. Depositing the raised frame layer can be performed before the forming the piezoelectric layer.

Another aspect of this disclosure is a method of manufacturing a bulk acoustic wave device. The method includes forming a piezoelectric layer over a first electrode and an acoustic reflector such that the piezoelectric layer has a recess, depositing a raised frame structure, and depositing a second electrode over the piezoelectric layer such that the recess and the raised frame structure are outside of a region in which the first electrode and the second electrode overlap and are on opposing sides of the piezoelectric layer.

Depositing the raised frame structure can be performed after the forming the piezoelectric layer. Depositing the raised frame structure can be performed before the forming the piezoelectric layer. Depositing the raised frame structure can be performed partly before and partly after the forming the piezoelectric layer.

Another aspect of this disclosure is a method of manufacturing an acoustic wave filter. The method includes manufacturing a first bulk acoustic wave resonator by at least (i) forming a piezoelectric layer over a first electrode such that the piezoelectric layer has a recess and (ii) depositing a second electrode over the piezoelectric layer such that the recess is outside of a region of the first bulk acoustic wave resonator in which the first electrode and the second electrode overlap and are on opposing sides of the piezoelectric layer; and electrically connecting the first bulk acoustic wave resonator with a second bulk acoustic wave resonator of the acoustic wave filter.

The acoustic wave filter can be included in a multiplexer. After manufacturing the acoustic wave filter can be configured to filter a radio frequency signal having a frequency in a range from 3.5 GHz to 7.125 GHz.

Another aspect of this disclosure is a bulk acoustic wave device having an active region. The bulk acoustic wave device includes an acoustic reflector, electrodes including a first electrode and a second electrode, a piezoelectric layer, and a frame structure over the acoustic reflector. The piezoelectric layer has a surface facing the acoustic reflector that is flat (a) over an entirety of the active region and (b) beyond the first electrode over the acoustic reflector. The first electrode and the second electrode overlap and are on opposing sides of the piezoelectric layer in the active region. The first electrode is between the piezoelectric layer and the acoustic reflector in the active region.

The frame structure can be outside of the active region.

The surface of the piezoelectric layer facing the acoustic reflector can be flat over an entirety of the acoustic reflector.

The bulk acoustic wave device can include a dielectric layer positioned between the piezoelectric layer and the acoustic reflector outside of the active region. The dielectric layer can be positioned laterally from the first electrode.

The frame structure can include a raised frame layer positioned on a same side of the piezoelectric layer as the first electrode. The frame structure can include a raised frame layer positioned on a same side of the piezoelectric layer as the second electrode. The frame structure can include a first raised frame layer positioned on a same side of the piezoelectric layer as the first electrode on a first electrode connection side of the bulk acoustic wave device, and a second raised frame layer positioned on a same side of the piezoelectric layer as the second electrode on a second electrode connection side of the bulk acoustic wave device.

The piezoelectric layer can include a recessed frame structure.

The bulk acoustic wave device can include a suspended frame structure. The bulk acoustic wave device can include metal shorted to the suspended frame structure, in which the metal is on an opposite side of the piezoelectric layer than the suspended frame structure. The bulk acoustic wave device can include a dielectric layer overlapping the suspended frame structure and positioned on an opposite side of the piezoelectric layer than the suspended frame structure, the dielectric layer can be positioned laterally from the first electrode.

The piezoelectric layer can have a recess over the acoustic reflector and outside of the active region.

The acoustic reflector can be an air cavity.

Another aspect of this disclosure is a bulk acoustic wave device having an active region. The bulk acoustic wave device includes an acoustic reflector; electrodes including a first electrode and a second electrode; and a piezoelectric layer having a recess outside of the active region, the first electrode positioned between the piezoelectric layer and the acoustic reflector in the active region, the piezoelectric layer having a surface facing the acoustic reflector that is planar (a) over an entirety of the active region and (b) beyond the first electrode over the acoustic reflector, the first electrode and the second electrode overlapping and being on opposing sides of the piezoelectric layer in the active region.

The surface of the piezoelectric layer facing the acoustic reflector can be planar over an entirety of the acoustic reflector.

The bulk acoustic wave device can include a dielectric layer positioned between the piezoelectric layer and the acoustic reflector outside of the active region, in which the dielectric layer is positioned laterally from the first electrode.

The bulk acoustic wave device can include a frame structure outside of the active region and at least partly over the acoustic reflector.

The piezoelectric layer can include a recessed frame structure.

The bulk acoustic wave device can include a suspended frame structure. The bulk acoustic wave device of can include metal shorted to the suspended frame structure, in which the metal is on an opposite side of the piezoelectric layer than the suspended frame structure. The bulk acoustic wave device can include a dielectric layer overlapping the suspended frame structure and positioned on an opposite side of the piezoelectric layer than the suspended frame structure, in which the dielectric layer is positioned laterally from the first electrode.

The acoustic reflector can be an air cavity.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

The present disclosure relates to U.S. patent application No. ______ [Attorney Docket SKYWRKS.1549A1], titled “BULK ACOUSTIC WAVE DEVICE INCLUDING PIEZOELECTRIC LAYER WITH RECESS,” filed on even date herewith, the entire disclosure of which is hereby incorporated by reference herein. The present disclosure relates to U.S. patent application No. ______ [Attorney Docket SKYWRKS.1549A2], titled “METHODS OF MANUFACTURING BULK ACOUSTIC WAVE DEVICE INCLUDING PIEZOELECTRIC LAYER WITH RECESS,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a cross-sectional diagram of a portion of bulk acoustic wave (BAW) device including a piezoelectric layer with a recess according to an embodiment.

FIG. 1B is a cross-sectional diagram of a portion of the BAW device of FIG. 1A around the recess with arrows indicating directions of power propagation.

FIG. 2A is a cross-sectional diagram of a portion of a BAW device including a piezoelectric layer with a recess and a step according to an embodiment. FIG. 2B is a cross-sectional diagram of a BAW device including a piezoelectric layer with a recess and a step according to an embodiment.

FIG. 3A is a cross-sectional diagram of a BAW device including a piezoelectric layer with a recess according to an embodiment. FIG. 3B is an example plan view of the BAW device of FIG. 3A.

FIG. 4A is a graph of quality factor at parallel resonance (Qp) for different dip and step heights in the BAW device of FIG. 3A. FIG. 4B is a graph of perimeter Qp for different dip and step heights in the BAW device of FIG. 3A.

FIG. 5 is a cross-sectional diagram of a portion of a BAW device including a piezoelectric layer with a recess and a support layer according to an embodiment.

FIG. 6 is a cross-sectional diagram of a BAW device including a piezoelectric layer with a recess that is tapered according to an embodiment.

FIG. 7 is a cross-sectional diagram of a BAW device including a piezoelectric layer with a recess and a recessed frame structure according to an embodiment.

FIG. 8 is a cross-sectional diagram of a BAW device including a piezoelectric layer with a recess and dielectric layer for achieving a flat bottom piezoelectric layer according to an embodiment.

FIG. 9 is a cross-sectional diagram of a BAW device including a piezoelectric layer with a recess and flat bottom according to an embodiment.

FIG. 10 is a cross-sectional diagram of a portion of BAW device including a piezoelectric layer with a recess and a raised frame structure over the piezoelectric layer according to an embodiment.

FIG. 11 is a cross-sectional diagram of a BAW device including a raised frame structure and piezoelectric layer with a recess, where the raised frame structure is included between the active region and the recess according to an embodiment.

FIG. 12 is a cross-sectional diagram of a BAW device including a piezoelectric layer with a recess and a raised frame structure on opposing sides of the piezoelectric layer according to an embodiment.

FIG. 13 is a cross-sectional diagram of a BAW device including a piezoelectric layer with a recess and a raised frame structure below the piezoelectric layer according to an embodiment.

FIG. 14 is a cross-sectional diagram of a BAW device including a piezoelectric layer with a recess and a suspended frame structure according to an embodiment.

FIG. 15 is a cross-sectional diagram of a BAW device including a piezoelectric layer with a recess and a suspended frame structure that is shorted to metal below the piezoelectric layer according to an embodiment.

FIG. 16 is a cross-sectional diagram of a BAW device including a piezoelectric layer with a recess and suspended frame structure that is shorted to metal below the piezoelectric layer according to another embodiment.

FIG. 17 is a cross-sectional diagram of a BAW device including a piezoelectric layer with a recess and suspended frame structure and a raised frame structure according to an embodiment.

FIG. 18 is a cross-sectional diagram of a BAW solidly mounted resonator (SMR) including a piezoelectric layer with a recess according to an embodiment.

FIGS. 19A, 19B, 19C, and 19D are cross-sectional diagrams of a BAW device during manufacturing where portions of a piezoelectric layer are etched to form a recessed frame structure and a recess according to an embodiment.

FIGS. 20A, 20B, 20C, 20D, and 20E are cross-sectional diagrams of a BAW device during manufacturing where a piezoelectric layer is selectively formed with different thicknesses in different regions according to an embodiment.

FIG. 21A is a schematic diagram of a ladder filter that includes one or more BAW resonators according to an embodiment.

FIG. 21B is schematic diagram of a band pass filter.

FIGS. 22A, 22B, 22C, and 22D are schematic diagrams of multiplexers that include a filter with one or more BAW resonators according to an embodiment.

FIGS. 23, 24, and 25 are schematic block diagrams of modules that include a filter with one or more BAW resonators according to an embodiment.

FIG. 26 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Achieving a high quality factor at parallel resonance (Qp) for a bulk acoustic wave (BAW) device in a filter design can be challenging. A relatively wide raised frame structure can lead to a high Qp. However, such a raised frame structure can introduce a raised frame mode and degrade an electromechanical coupling coefficient (kt²). Qp can also drop relatively rapidly as the BAW device area shrinks due to insufficient lateral energy confinement with current frame designs. Aspects of this disclosure relate to (1) suppressing and/or eliminating raised frame and kt² degradation for frame geometries and/or (2) improving energy confinement in the BAW device so that Qp becomes less sensitive to area reduction.

Increasing the quality factor (Q) of a given BAW resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by having a recess in a piezoelectric layer. Such a recess can suppress an asymmetric mode. A recess can provide a geometric discontinuity that can cause a Lamb wave to be reflected.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of material that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device. This resonance can be below a main resonant frequency of the BAW device. A resonance associated with the raised frame structure can be referred to as a raised frame mode. The raised frame mode can be undesirable in certain applications.

In BAW devices disclosed herein, the frame structure can be outside of an active region of a BAW device in which a pair of electrodes overlap on opposing sides of a piezoelectric layer over an acoustic reflector. With such a position of the frame structure, there can be no significant excitation of a frame mode.

This disclosure provides technical solutions that can suppress and/or eliminate one or more frame modes. At the same time, technical solutions disclosed herein can maintain a desired electromechanical coupling coefficient (kt²) and significantly increase a quality factor (Q) of a BAW device. BAW devices disclosed herein can achieve significant performance improvements over other BAW devices. Filters that include BAW devices disclosed herein can provide improved performance in a variety of applications, such as but not limited to fifth generation (5G) New Radio (NR) applications. BAW devices disclosed herein can improve performance in applications where a plurality of filters are connected together with each other.

Aspects of this disclosure relate to a BAW device that includes a piezoelectric layer with a recess. The recess can be positioned outside of an active region of the BAW device in which the first electrode and the second electrode overlap with each other and are positioned on opposing sides of the piezoelectric layer. For example, the piezoelectric layer can include an etched region where there is no electrical excitation. This can contribute to confining energy in the active region of the BAW device. The recess can be over the acoustic reflector of the BAW device. The recess can suppress asymmetric modes. The BAW device can include a frame structure outside of the action region. The frame structure can surround the active region in plan view. The frame structure can include a raised frame structure. The raised frame structure can suppress symmetric modes.

Aspects of this disclosure relate to manufacturing a BAW device that includes a piezoelectric layer having a recess. The piezoelectric layer has different thicknesses in different regions of the BAW device. The recess can be formed by etching piezoelectric material in certain applications. The recess can be formed by selectively growing piezoelectric material in some applications.

BAW devices disclosed herein can significantly attenuate one more spurious modes and achieve relatively high Q, while maintaining kt² at a relatively stable level. This can effectively decouple Q, kt² and strength of spurious modes in BAW devices.

BAW Devices with Piezoelectric Layer Having Recess

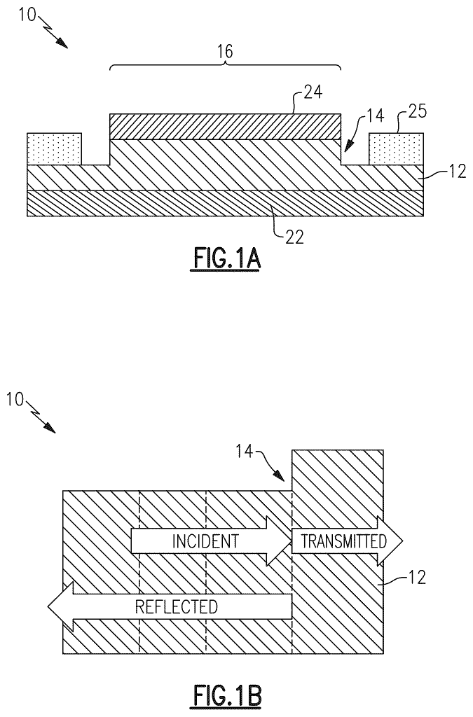

A BAW device can include a piezoelectric layer with a recess. The recess can be in a peripheral region of the BAW device. Examples of such a BAW device will be discussed with reference to FIGS. 1A to 18. Any suitable principles and advantages of these BAW devices can be implemented together with each other and/or with any suitable principles and advantages of other embodiments disclosed herein. BAW devices disclosed herein can be BAW resonators.

FIG. 1A is a cross-sectional diagram of a portion of a bulk acoustic wave (BAW) device 10 including a piezoelectric layer 12 with a recess 14 according to an embodiment. The recess 14 of the piezoelectric layer 12 is outside of an active region 16 of the BAW device 10. In FIG. 1A, an electrode and piezoelectric stack of the BAW device 10 is illustrated. The BAW device 10 includes additional elements that are not illustrated, such as an acoustic reflector. Referring to FIG. 1A, the BAW device 10 includes the piezoelectric layer 12 with the recess 14, a first electrode 22, a second electrode 24, and a raised frame structure 25. The first electrode 22 and the second electrode 24 overlap on opposing sides of the piezoelectric layer 12 in the active region 16 of the BAW device 10. The raised frame structure 25 is outside of the active region 16 in the BAW device 10. The raised frame structure 25 can include any suitable metal raised frame structure and/or any suitable dielectric raised frame structure. By having the raised frame structure 25 outside of the active region 16, there can be little or no acoustic activity from the frame structure 25.

FIG. 1B is a cross-sectional diagram of a portion of piezoelectric layer 12 of the BAW device 10 of FIG. 1A around the recess 14 with arrows indicating directions of power propagation. The recess 14 is an example of a discontinuity in the piezoelectric layer 12. A geometric discontinuity in a passive region of the BAW device 10 can cause a reflected wave to enter another passive region away from the active region. The geometric discontinuity can be one or more of a dip, a step, a notch, or a trench in the piezoelectric layer 12 that can cause Lamb wave reflection. Without considering bulk loss, the reflected power divided by the incident power can be used to evaluate the discontinuity design. Stronger reflection associated with better energy confinement can be preferred. The discontinuity can be a recess. The discontinuity can be associated with a raised frame and/or a recessed frame in certain applications.

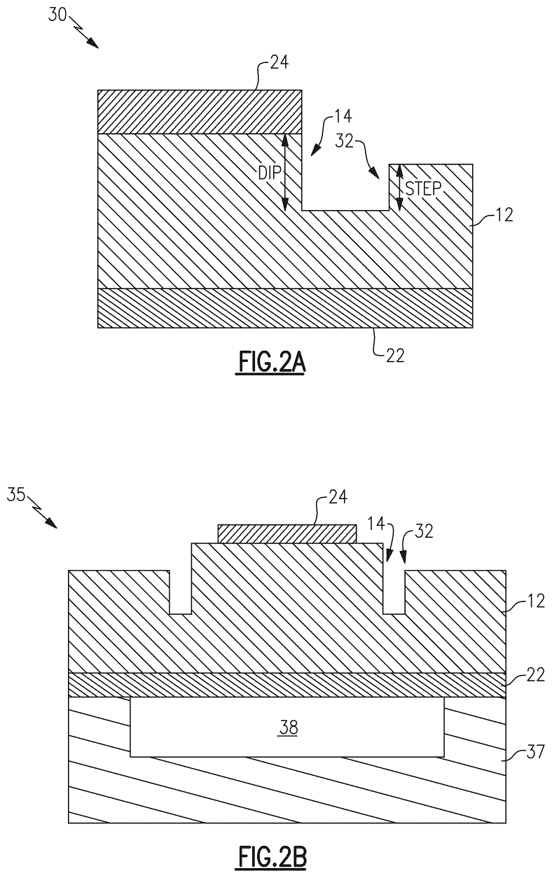

FIG. 2A is a cross-sectional diagram of a portion of a BAW device 30 including a piezoelectric layer 12 with a recess 14 and a step 32 according to an embodiment. The recess 14 can be a dip in the piezoelectric layer 12. In the BAW device 30, the piezoelectric layer 12 has a first thickness in the active region, a second thickness in a recessed region adjacent to the active region, and a third thickness that is between the first thickness and the second thickness in an outer region, where the recessed region is between the active region and the outer region. A piezoelectric layer 12 with the recess 14 and the step 32 can provide a desirable reflected power ratio in the BAW device 30.

FIG. 2B is a cross-sectional diagram of a BAW device 35 including a piezoelectric layer 12 with a recess 14 and a step 32 according to an embodiment. FIG. 2B also illustrates a support substrate 37 and an air cavity 38 of the BAW device 35. Simulations were run with the BAW device 35 as a 50 Ohm resonator with a first electrode 22 that is a ruthenium electrode, a second electrode 24 that is a ruthenium electrode, and a support substrate 37 that is a silicon substrate. Simulations indicate that perimeter loss was just around 2.6% at a parallel resonance frequency. In this case, Qp would be almost independent of the area scaling. The perimeter loss in the simulations for the BAW device 35 is a significant improvement over certain current BAW devices in transmit bandpass filters.

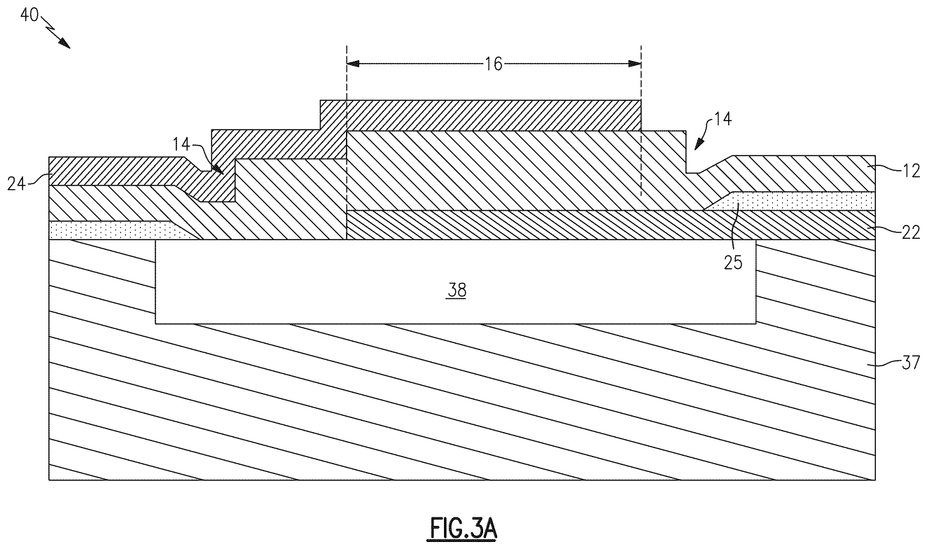

FIG. 3A is a cross-sectional diagram of a BAW device 40 including a piezoelectric layer 12 with a recess 14 according to an embodiment. As illustrated, the BAW device 40 includes the piezoelectric layer 12 with a recess 14, a first electrode 22, a second electrode 24, a raised frame structure 25, a support substrate 37, and an air cavity 38. In the BAW device 40, the piezoelectric layer 12 with the recess 14 together with the raised frame structure 25 can improve energy confinement. The recess 14 of the piezoelectric layer 12 can suppress asymmetric modes. The raised frame structure 25 can suppress symmetric modes. The BAW device 40 also includes the frame structure 25 outside of an active region 16. In the active region 16, the first electrode 22 and the second electrode 24 overlap on opposing side of the piezoelectric layer 12 over the air cavity 38. As illustrated in FIG. 3A, the raised frame structure 25 is in a passive region of the BAW device 40. The raised frame mode and kt² degradation associated with the raised frame structure 25 can be avoided with the positioning of the raised frame structure 25 in the BAW device 40.

In the BAW device 40, the piezoelectric layer 12 can be etched to form the recess 14. The recess 14 can be present around a perimeter of the BAW device 40. The recess 14 can be a trench, for example. The recess 14 is shown on opposing sides of the active region 16 of the BAW device 40 in the cross-sectional view of FIG. 3A. The piezoelectric layer 12 has a first thickness in the active region 16 and a second thickness in a recessed region corresponding to the recess 14, where the second thickness is less than the first thickness. The second thickness can be less than 50% of the first thickness in certain applications. The piezoelectric layer 12 can also have the first thickness in an intermediate region between the active region 16 and the recessed region, for example, as shown in FIG. 3A. In the BAW device 40, the step in the piezoelectric layer 12 associated with the recess 14 is between the active region 16 and the raised frame structure 25.

The piezoelectric layer 12 can be formed of any suitable piezoelectric material such as, but not limited to, aluminum nitride (AlN), zinc oxide (ZnO), or lead zirconium titanate (PZT). In certain applications, the piezoelectric layer 12 can include AlN. The piezoelectric material of the piezoelectric layer 12 can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), calcium (Ca), boron (B), carbon (C), europium (Eu), or the like. In certain applications, the piezoelectric layer 12 can be AlN based layer doped with Sc. Doping the piezoelectric layer 12 can adjust the resonant frequency. Doping the first piezoelectric layer 12 can increase the kt² of the BAW device 40. Doping to increase the kt² can be advantageous at higher frequencies where kt² can be degraded.

In certain applications, two or more piezoelectric layers in accordance with any suitable principles and advantages disclosed herein can be stacked with each other between electrodes of a BAW device. The stacked piezoelectric layers can have c-axes oriented in opposite directions in the active region and excite an overtone mode as a main mode of a BAW resonator. One or more of the stacked piezoelectric layers can include a recess in accordance with any suitable principles and advantages disclosed herein. A BAW device that excites an overtone mode as a main mode can include a piezoelectric layer having a recess in accordance with any suitable principles and advantages disclosed herein.

Referring to FIG. 3A, the piezoelectric layer 12 is positioned between the first electrode 22 and the second electrode 24 throughout the entire the active region 16. The first electrode 22 can be referred to as a lower electrode. The first electrode 22 can have a relatively high acoustic impedance. The first electrode 22 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 24 can have a relatively high acoustic impedance. The second electrode 24 can include Mo, W, Ru, Cr, Ir, Pt, Ir/Pt, or any suitable alloy and/or combination thereof. The second electrode 24 can be formed of the same material as the first electrode 22 in certain applications. For example, in some applications the first electrode 22 and the second electrode 24 can be ruthenium electrodes. The second electrode 24 can be referred to as an upper electrode. The thickness of the first electrode 22 can be approximately the same as the thickness of the second electrode 24 in the acoustically active region 16 of the BAW device 40.

The raised frame structure 25 is outside of the active region 16 and positioned further from the active region 16 than where the piezoelectric layer 12 includes a dip in the BAW device 40. With the raised frame structure 25 being outside of the active region 16, there can be little or no acoustic activity associated with the raised frame structure 25. Accordingly, there can be no significant raised frame mode associated with the raised frame structure 25 in the BAW device 40. Other BAW devices with a piezoelectric layer that includes a recess outside of the active region can include a recessed frame structure and/or a plurality of raised frame structures.

The raised frame structure 25 can include any suitable metal or oxide. For example, the raised frame layer 25 can include a metal layer having the same material as the first electrode 22 and/or the second electrode 24 of the BAW device 40. This can be convenient from a manufacturing perspective. The raised frame structure 25 can be a relatively high density material in certain applications. For instance, the second raised frame layer 24 can include Mo, W, Ru, the like, or any suitable alloy thereof. In some applications, the raised frame layer 25 can be a dielectric layer, such a silicon dioxide (SiO₂) layer, a silicon nitride (SiN) layer, a silicon carbide (SiC) layer, or any other suitable dielectric layer. For example, the raised frame layer 25 can be a silicon dioxide layer in certain applications. Because silicon dioxide is already used in a variety of BAW devices, manufacturing a raised frame layer 25 with a silicon dioxide can be relatively easy. The raised frame structure 25 can be formed by a layer that extends beyond the air cavity 38 of the BAW device 40. This can be for manufacturability reasons in certain instances.

The piezoelectric layer 12 and the electrodes 22 and 24 are positioned over a support substrate 37. The support substrate 37 can be a semiconductor substrate. The support substrate 37 can be a silicon substrate. The support substrate 37 can be any other suitable support substrate, such as a quartz substrate, a silicon carbide substrate, a sapphire substrate, a glass substrate, or any suitable ceramic (e.g., spinel, alumina, etc.) substrate.

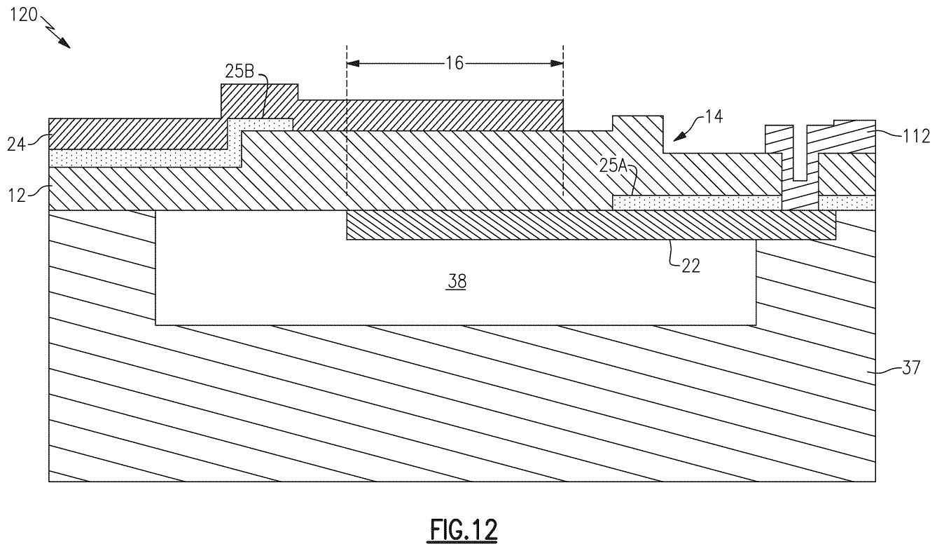

As illustrated in FIG. 3A, the air cavity 38 is located above the support substrate 37. The air cavity 38 is an example of an acoustic reflector. The air cavity 38 is positioned between the support substrate 37 and the first electrode 22. In the BAW device 40, both a recess 14 in the piezoelectric layer 12 and at least a portion of the raised frame structure 25 are positioned over the air cavity 38. In some applications, an air cavity 38 can be etched into a support substrate 37, for example, as shown in FIG. 3A. In various applications, an air cavity can be over a support substrate. In certain applications, a solid acoustic mirror with alternating high acoustic impedance and low acoustic impedance layers can be included in place of an air cavity, for example as shown in FIG. 18. A BAW device with an air cavity can be referred to as a film bulk acoustic wave resonator (FBAR). A BAW device with a solid acoustic mirror can be referred to as a BAW solidly mounted resonator (SMR).

The BAW device 40 can include one or more passivation layer that are not illustrated in FIG. 3A. The BAW device 40 can include one or more seed layers not illustrated in FIG. 3A.

The active region 16 of the BAW device 30 corresponds to where electrodes 22 and 24 overlap with each other over the air cavity 38. Voltage can be applied on opposing sides of the piezoelectric layer 12 in the active region 16 to generate a bulk acoustic wave in the piezoelectric layer 12. The active region 16 can provide a main mode of the BAW device 40. The main mode can be the mode with the highest coupling or highest kt². The active region 16 can be the central part of the BAW device 40 is free from the from any frame structures, such as the raised frame structure 25, and that is also free from the recess 14 of the piezoelectric layer 12. The active region 16 can be surrounded by the recess 14 in plan view. The raised frame structure 25 can surround the active region 16 in plan view.

While the BAW device 40 includes the raised frame structure 25, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented together with a recessed frame structure. In some other applications, a recessed frame structure can be implemented in a BAW device without a raised frame structure. Moreover, a raised frame structure 25 can be located in a variety of positions in a BAW device material stack.

FIG. 3B is an example plan view of the BAW device 40 of FIG. 3A. The cross-sectional view of FIG. 3A can be along the line from A to A′ in FIG. 3B. In FIG. 3B, the active region 16, an intermediate region 44, and a frame region 45 are shown. As illustrated, the active region 16 can correspond to the majority of the area of the BAW device 40. The intermediate region 44 is between the active region 16 and the frame region 45 in FIG. 3B. The intermediate region 44 can be a passive region in which (1) there is an electrode on only one side of the piezoelectric layer 12 and (2) there is no frame structure. There can be a dip in the piezoelectric layer 12 in the intermediate region 44 where the piezoelectric layer 12 transitions from a thickness from the active region to a thickness of a recessed region. The frame region 45 surrounds active region 16 and the intermediate region 44 in plan view. The frame region 45 includes the raised frame structure 25 of the BAW device 40 of FIG. 3A. In some other instances, a frame region can include one or more additional raised frame structures and/or one or more recessed frame structures.

FIG. 3B illustrates the BAW device 40 with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides, or the like.

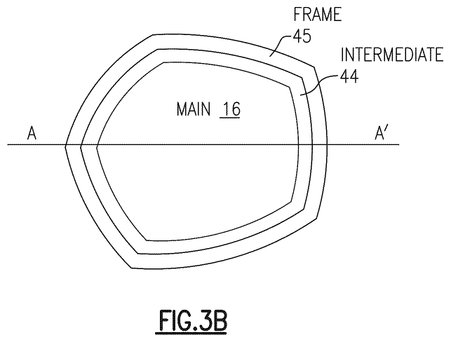

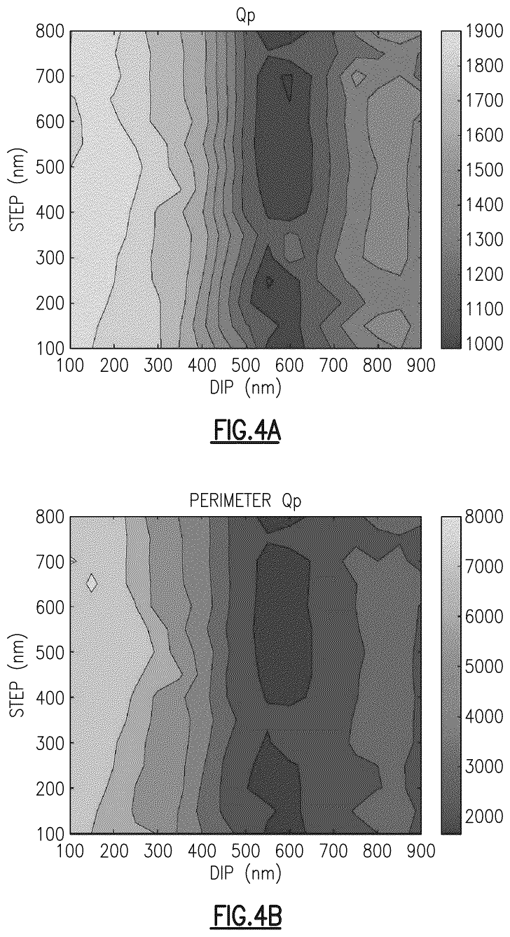

FIG. 4A is a graph of quality factor at parallel resonance (Qp) for different dip and step heights in the BAW device 40 of FIG. 3A. FIG. 4B is a graph of perimeter Qp for different dip and step heights in the BAW device 40 of FIG. 3A. The dip can correspond to a depth of an etch in the piezoelectric layer 12 that creates the recess 14. The step height can correspond to the thickness of the raised frame structure 25. FIGS. 4A and 4B indicate that a ratio of perimeter Qp divided by Qp for the BAW device 40 can be in a range from about 3.7 to 4.2. This ratio is higher than in a variety of current BAW devices in transmit bandpass filters. Further Qp improvement can be achieved by through design of the frame structures on the top electrode and/or bottom electrode connections sides.

A variety of additional BAW devices that include a piezoelectric layer with a recess are disclosed herein. Such BAW devices can be implemented with or without a raised frame structure. A discontinuity in the piezoelectric layer associated with the recess can be closer to the active region than a raised frame structure. Alternatively, a discontinuity in the piezoelectric layer associated with the recess can farther from to the active region than a raised frame structure. A raised frame structure can be located in a variety of positions relative to the piezoelectric layer. For example, a raised frame layer can be positioned above the piezoelectric layer, below the piezoelectric, or embedded in the piezoelectric layer. Moreover, two or more raised frame layers can be included in a BAW device in accordance with any suitable principles and advantages disclosed herein. A frame structure can include a metal layer and/or a dielectric layer. In some instances, a bottom surface of the piezoelectric layer can be flat over an entire acoustic reflector. There can be a dielectric filler layer under such a piezoelectric layer in some instances. Some BAW devices can include a suspended frame structure. On one side of a BAW resonator, metal can be shorted on opposing sides of the piezoelectric layer. Various acoustic reflectors can be included in BAW devices. Any suitable combination of features of the BAW devices disclosed herein can be implemented together with each other. Additional BAW devices will be discussed with reference to FIGS. 5 to 18.

FIG. 5 is a cross-sectional diagram of a portion of a BAW device 50 including a piezoelectric layer 12 with a recess 14 and a support layer 52 according to an embodiment. The support layer 52 can provide mechanical support in the BAW device 50. This can improve mechanical robustness of the BAW device 50. The BAW device 50 can achieve a desirable Qp. The support layer 52 can be positioned between the first electrode 22 and a support substrate (not illustrated in FIG. 5) and/or an air cavity (not illustrated in FIG. 5). As illustrated, the support layer 52 can be included in a recessed region of the piezoelectric layer 12. The support layer 52 can overlap with the raised frame structure 25. The support layer 52 can include any suitable material, such as a dielectric, a metal, or a semiconductor. With the support layer 52, the raised frame structure 25 can be thinner than in a similar BAW device without the support layer 52 in certain applications.

FIG. 6 is a cross-sectional diagram of a BAW device 60 including a piezoelectric layer 12 with a recess 14 that is tapered according to an embodiment. The BAW device 60 is like the BAW device 40 of FIG. 3A, except that the recess 14 of the BAW device 60 includes a tapered edge 62. The tapered shape of the recess 14 can provide robustness and better energy confinement in certain applications. The recess 14 can surround the active region 16 in plan view. The recess 14 can include a tapered edge 62 on opposing sides of the active region 16 in a cross sectional view.

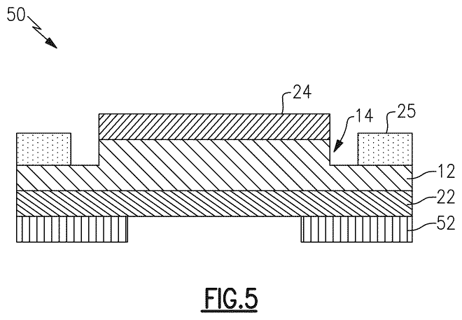

FIG. 7 is a cross-sectional diagram of a BAW device 70 including a piezoelectric layer with a recess 14 and a recessed frame structure 75 according to an embodiment. The recessed frame structure 75 is in a recessed frame region 76 of the BAW device 70. The recessed frame region 76 can surround the active region 16 in plan view. As illustrated in FIG. 7, the recessed frame structure 75 can be positioned between the active region 16 and the recess 14. Accordingly, the recessed frame structure 75 can be positioned between the active region 16 and a trench in the piezoelectric layer 12.

In the BAW device 70, the piezoelectric layer 12 has first thickness in the active region 16, a second thickness in a recessed region where the piezoelectric layer 12 has the recess 14, and a third thickness in the recessed frame region 76. The difference between the third thickness and the first thickness can be a recessed frame thickness T_ReF. The recessed frame thickness T_ReF can represent an amount by which the piezoelectric layer 12 thickness is reduced in the recessed frame region 76 relative to in the active region 16.

The recessed frame structure 75 can be formed by etching the piezoelectric layer 12 in certain applications. For example, the piezoelectric layer 12 can be etched to reduce the thickness of the piezoelectric layer 12 by the recessed frame thickness T_ReF. The piezoelectric layer 12 can be further etched to form the recess 14 in certain applications.

In some applications, the piezoelectric layer 12 of the BAW device 70 can be formed by selective growth of piezoelectric material. For example, piezoelectric material can be formed to the thickness for the recessed region, then additional piezoelectric material can be formed in the recessed frame region 76 and the active region 16, and then further piezoelectric material can be formed in the active region 16 to create the piezoelectric layer 12 of the BAW device 70.

In embodiments disclosed herein, a frame structure can be located outside of an active region of a BAW device in which electrodes of the BAW device overlap over an acoustic reflector. In BAW devices, it can be desirable for the piezoelectric layer to have a flat bottom surface over all or nearly all of the acoustic reflector. For example, such a flat bottom surface can reduce the probability of the piezoelectric layer 12 cracking. In some BAW devices with a frame structure outside of the active region, the geometry of the lower electrode can present technical challenges to manufacturing the piezoelectric layer with a flat lower side facing an acoustic reflector.

FIG. 8 is a cross-sectional diagram of a BAW device 80 including a piezoelectric layer 12 with a recess 14 and dielectric layer 84 for achieving a flat bottom of the piezoelectric layer 12 according to an embodiment. The BAW device 80 is like the BAW device 30 of FIG. 3A, except that the BAW device 80 additionally includes the dielectric layer 84. The dielectric layer 84 can have generally the same thickness as the first electrode 22. With the dielectric layer 84, more of a bottom surface of the piezoelectric layer 12 of the BAW device 80 is flat and planar than a bottom surface of the piezoelectric layer 12 of the BAW device 30 of FIG. 3A. The bottom surface of the piezoelectric layer 12 of the BAW device 80 is the surface that faces the air cavity 38. As illustrated in FIG. 8, the bottom surface of the piezoelectric layer 12 is flat and planar over the air cavity 38 except where the piezoelectric layer 12 is in contact with the raised frame structure 25. The bottom surface of the piezoelectric layer 12 is flat over the entire acoustic reflector except in the raised frame region in the BAW device 80. A generally flat bottom of the piezoelectric layer 12 can avoid and/or reduce the probability of the piezoelectric layer 12 cracking.

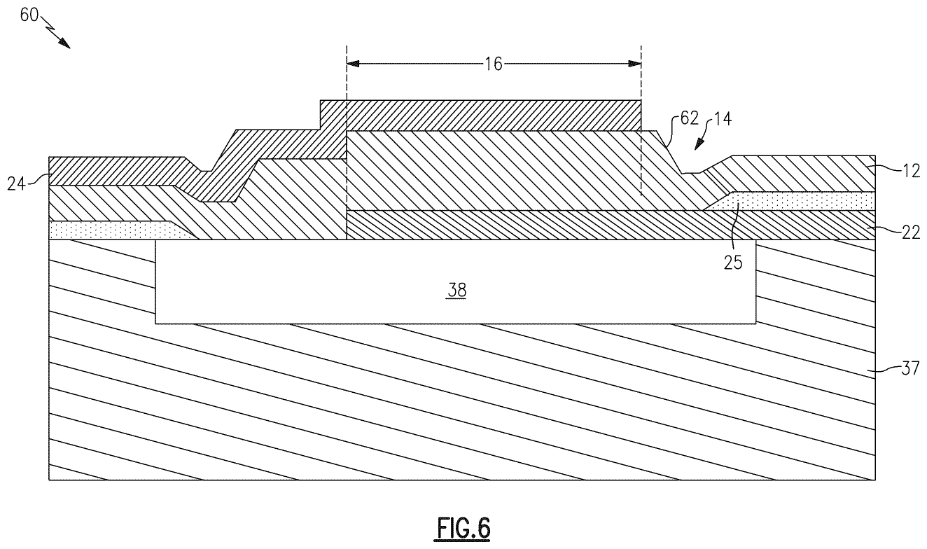

FIG. 9 is a cross-sectional diagram of a BAW device 90 including a piezoelectric layer 12 with a recess 14 and flat bottom according to an embodiment. The BAW device 90 is like the BAW device 80 of FIG. 8, except that the BAW device 90 does not include the dielectric layer 84. The generally flat bottom surface of the piezoelectric layer 12 can be formed using a sacrificial layer that is removed during manufacturing. The piezoelectric layer 12 can be formed over a planar surface created by the sacrificial layer and the first electrode 22. Then the sacrificial layer can be removed. For example, the sacrificial layer can be removed when creating the air cavity 38. In this example, the sacrificial layer can be formed of the same material as the sacrificial layer that is removed to form the air cavity 38.

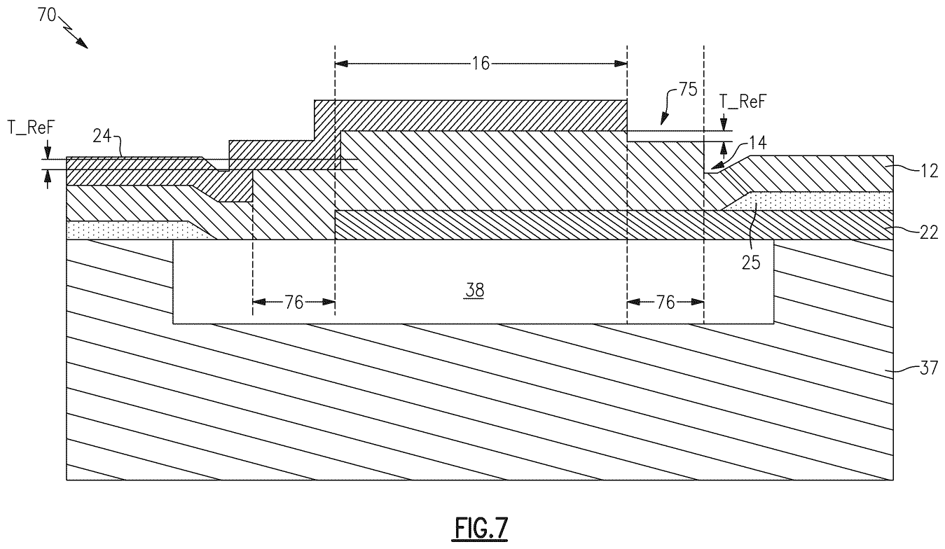

FIG. 10 is a cross-sectional diagram of a portion of a BAW device 100 including a piezoelectric layer 12 with a recess 14 and a raised frame structure 25 over the piezoelectric layer 12 according to an embodiment. In the BAW device 100, the raised frame structure 25 is positioned between the active region and the recess 14 in the piezoelectric layer 12. The raised frame structure 25 is closer to the active region than the recess 14 is from the active region.

FIG. 11 is a cross-sectional diagram of a BAW device 110 including a raised frame structure 25 and piezoelectric layer 12 with a recess 14, where the raised frame structure 25 is included between the active region 16 and the recess 14 according to an embodiment. When the raised frame structure 25 is closer to the active region 16 than the recess 14 is to the active region 16, a propagating acoustic wave generated in the active region 16 can see the raised frame structure 25 first and then the recess 14 when propagating toward the outer edges of the BAW device 110. The raised frame structure 25 can confine symmetric modes. The recess 14 can confine asymmetric modes.

In the BAW device 110, the raised frame structure 25 is on a opposite side of the piezoelectric layer 12 than the air cavity 38. The piezoelectric layer 12 has a flat surface facing the air cavity 38 in the BAW device 110. The piezoelectric layer 12 can have a bottom surface that is flat over an entire acoustic reflector, for example, as illustrated in FIG. 11. The BAW device 110 includes a metal connector 112 that is connected with the first electrode 22. The metal connector 112 can be formed of the same material and/or during the same deposition step as the second electrode 24. The metal connector 112 can electrically connect the first electrode 22 to one or more other conductive structures.

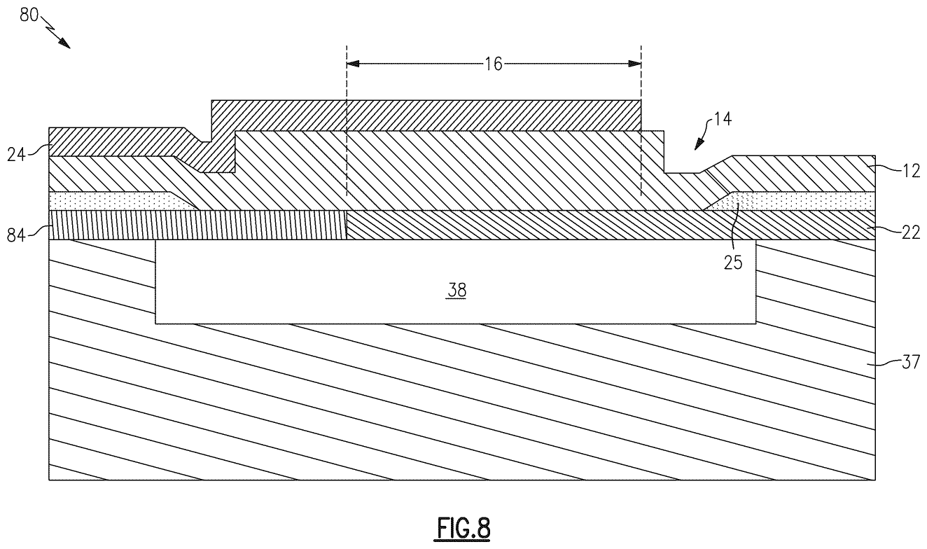

FIG. 12 is a cross-sectional diagram of a BAW device 120 including a piezoelectric layer 12 with a recess 14 and a raised frame structure 25A and 25B on opposing sides of the piezoelectric layer 12 according to an embodiment. In the BAW device 120, the raised frame structure 25A and 25B is positioned between the active region 16 and the recess 14. The BAW device 120 is like the BAW device 110 of FIG. 11, except that the raised frame structure 25A and 25B of the BAW device 120 is included on opposite sides of the piezoelectric layer 12 on opposite electrode connection sides of the BAW device 120. The raised frame structure 25A on the first electrode 22 connecting side of the BAW device 120 is positioned under the piezoelectric layer 12. The raised frame structure 25A is positioned between the piezoelectric layer 12 and the first electrode 22 in FIG. 12. The raised frame structure 25B on the second electrode 24 connecting side of the BAW device 120 is positioned over the piezoelectric layer 12. The raised frame structure 25B is positioned between the piezoelectric layer 12 and the second electrode 24 in FIG. 12. The stacks outside of the active region 16 of the BAW device 120 can be more symmetric on opposing sides than in some other BAW devices. In the BAW device 120, acoustic energy can be effectively confined with one etch depth of the piezoelectric layer 12 and one thickness for the raised frame structures 25A and 25B that are positioned on opposing sides of the piezoelectric layer 12. The raised frame layer 25A and the raised frame layer 25B can be deposited in separate deposition steps.

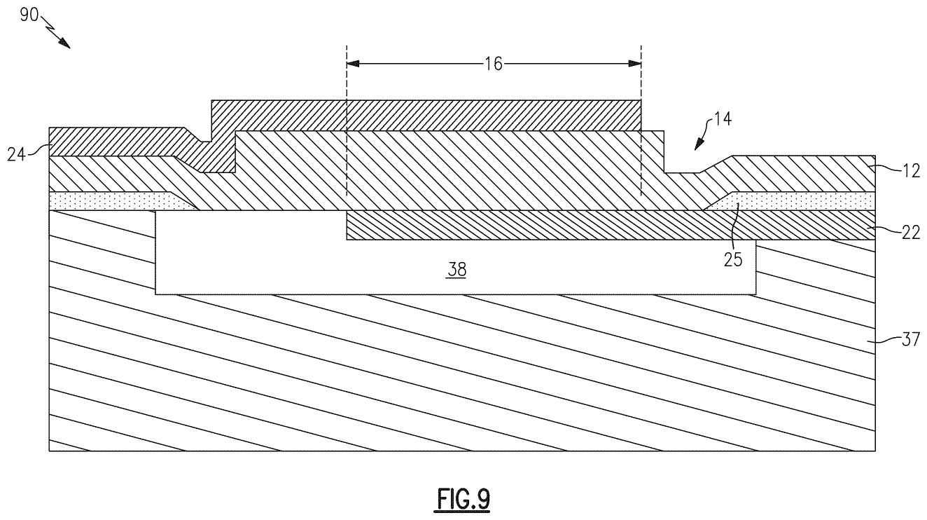

FIG. 13 is a cross-sectional diagram of a BAW device 130 including a piezoelectric layer 12 with a recess 14 and a raised frame structure 25 below the piezoelectric layer 12 according to an embodiment. In BAW device 130, the raised frame structure 25 is included between the active region 16 and the recess 14. The BAW device 140 is like the BAW device 110 of FIG. 11, except that the raised frame structure 25 of the BAW device 130 is included below the piezoelectric layer 12 and the raised frame structure 25 of the BAW device 110 is included above the piezoelectric layer 12. The raised frame structure 25 is positioned between the piezoelectric layer 12 and the air cavity 38 on both the first electrode 22 connection side and the second electrode 24 connection side in the BAW device 130. The bottom surface of the piezoelectric layer 12 is not flat over the entire air cavity 38 in the BAW device 130. The stacks outside of the active region 16 are different on the first electrode 22 connection side and the second electrode 24 connection side in the BAW device 130.

BAW devices that include a piezoelectric layer with a recess can also include a suspended frame structure. The suspended frame structure can include metal extending from a top electrode over an air gap to a top electrode connection side of the BAW device. The stack thickness in the recessed region of the piezoelectric layer of such a BAW device can be thinner than in some other embodiments. The thinner stack in this region can improve energy confinement within the active area of the BAW device. Example BAW devices with suspended frame structures are shown in and will be described with reference to FIGS. 14 to 17. Any suitable principles and advantages of these BAW devices can be implemented together with each other and/or with any suitable principles and advantages of other embodiments disclosed herein.

FIG. 14 is a cross-sectional diagram of a BAW device 140 including a piezoelectric layer 12 with a recess 14 and a suspended frame structure 141 according to an embodiment. The BAW device 140 includes a dielectric layer 84 between the piezoelectric layer 12 and the air cavity 38. The piezoelectric layer 12 can be formed over the dielectric layer 84 and the first electrode 22 such that the piezoelectric layer 12 has a flat bottom surface that is facing the air cavity 38. In the BAW device 140, the second electrode 24 extends over the piezoelectric layer 12 on one side of the illustrated cross-sectional view. An air gap 142 can be included between the suspended frame structure 141 and the piezoelectric layer 12. The suspended frame structure 141 is on a second electrode 24 connection side of the BAW device 140. The stack thickness in the recessed region of the piezoelectric layer 12 can be significantly thinner than in the BAW device 80 of FIG. 8. The thinner stack thickness in the recessed region of the piezoelectric layer 12 in the BAW device 140 can provide better acoustic energy confinement.

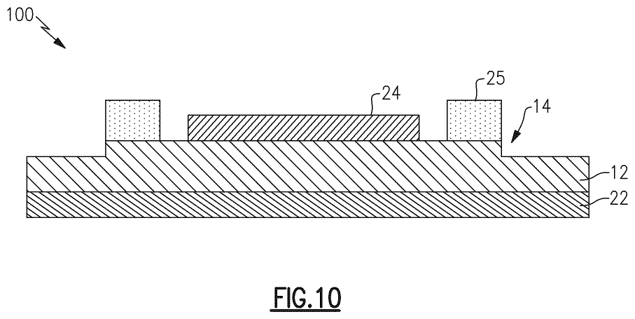

FIG. 15 is a cross-sectional diagram of a BAW device 150 including a piezoelectric layer 12 with a recess 14 and a suspended frame structure 141 that is shorted to metal 151 below the piezoelectric layer 12 according to an embodiment. The BAW device 150 is like the BAW device 140 of FIG. 14, except that the BAW device 150 (a) includes metal 151 below the piezoelectric layer 12 that is connected to the suspended frame structure 141 and (b) has a smaller dielectric layer 84 that is positioned between the metal 151 and the first electrode 22. The metal 151 is electrically connected to the second electrode 24. Accordingly, the metal 151 should be at the same potential as the second electrode 24. The metal 151 is in the same metal layer as the first electrode 22. Accordingly, the metal 151 can be formed in the same deposition step as the first electrode 22. The metal 151 can be the same material as the first electrode 22. With the metal 151 under the piezoelectric layer 12, there can be a more symmetric frame structure in the recessed region of the piezoelectric layer 12 on one side of the cross-section of the BAW device 150. The metal 151 in BAW device 150 can improve thermal dissipation and/or reduce Ohmic loss.

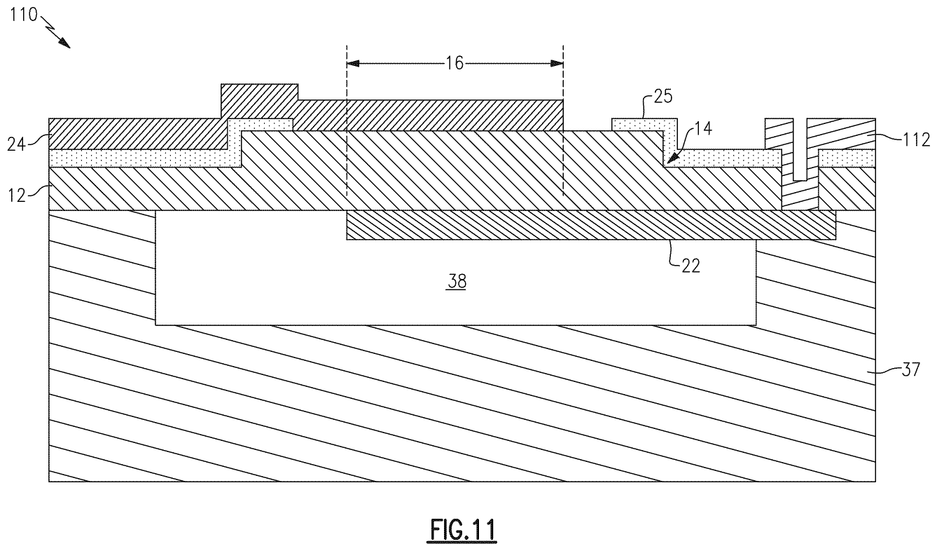

FIG. 16 is a cross-sectional diagram of a BAW device 160 including a piezoelectric layer 12 with a recess 14 and suspended frame structure 141 that is shorted to metal 151 below the piezoelectric layer 12 according to another embodiment. The BAW device 160 is like the BAW device 150 of FIG. 15, except that the BAW device 160 does not include the dielectric layer 84. During manufacturing of the BAW device 150, a sacrificial layer can be included and removed instead of including a dielectric layer 84 that is included in the BAW device 140 after manufacture. The sacrificial layer can be of the same material as sacrificial material used to form the air cavity 38.

FIG. 17 is a cross-sectional diagram of a BAW device 170 including a piezoelectric layer 12 with a recess 14 and suspended frame structure 141 and a raised frame structure 25 according to an embodiment. The BAW device 170 is like the BAW device 160 of FIG. 16, except that the BAW device 170 additionally includes a raised frame structure 25. With the raised frame structure 25, the piezoelectric layer 12 and the air gap 142 have different geometries in the BAW device 170 than in the BAW device 160. The raised frame structure 25 can further improve Qp.

BAW devices that include a piezoelectric layer with a recess can include any suitable acoustic reflector. While embodiments of BAW devices are disclosed with an air cavity etched into a support substrate, a BAW device with an air cavity over the support substrate and/or a solid acoustic mirror as an acoustic reflector can be implemented in accordance with any suitable principles and advantages disclosed herein.

FIG. 18 is a cross-sectional diagram of a BAW device 180 including a solid acoustic mirror 182 and piezoelectric layer 12 with a recess 14 according to an embodiment. The BAW device 180 is a BAW SMR. The BAW device 180 includes a solid acoustic mirror 182 in place of an air cavity as an acoustic reflector. The BAW device 180 is like the BAW device 130 of FIG. 3A, except that the BAW device 180 is a BAW SMR instead of an FBAR. In the BAW device 180, the solid acoustic mirror 182 is an acoustic Bragg reflector that functions as an acoustic reflector. The solid acoustic mirror 182 is positioned between the first electrode 22 and the support substrate 37. The illustrated solid acoustic mirror 182 includes alternating low impedance and high impedance layers 183 and 184, respectively. As an example, the solid acoustic mirror 182 can include alternating silicon dioxide layers and tungsten layers. As another example, the solid acoustic mirror 182 can include alternating silicon dioxide layers and molybdenum layers. The support substrate 37 is typically thicker than the solid acoustic mirror 182. In certain applications (not illustrated), a BAW SMR can also include a second solid acoustic mirror over a second electrode 24 in at least an active region 16. Any other suitable features of a BAW SMR can alternatively or additionally be implemented in a BAW device with a piezoelectric layer having a recess in accordance with any suitable principles and advantages disclosed herein. Any suitable principles and advantages disclosed herein with reference to FBARs be applied to BAW SMRs.

Methods of Manufacturing BAW Device with Piezoelectric Layer Having Recess

BAW devices that include a piezoelectric layer with recess in accordance with any suitable principles and advantages disclosed herein can be manufactured using a variety of methods. The recess can be formed by etching material of the piezoelectric layer. Alternatively or additionally, the recess can be formed from selective piezoelectric layer growth. A BAW device can be manufactured in accordance with any suitable principles and advantages of any of the methods disclosed herein.

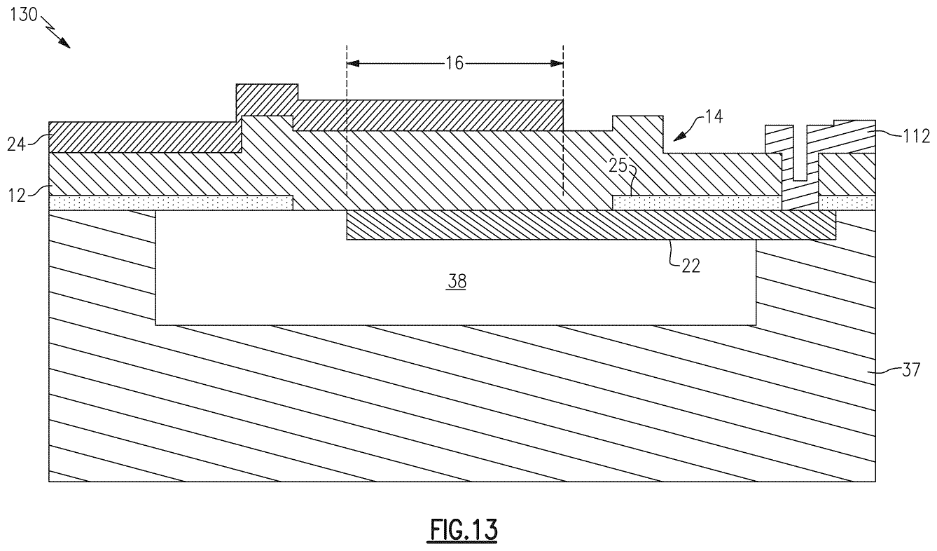

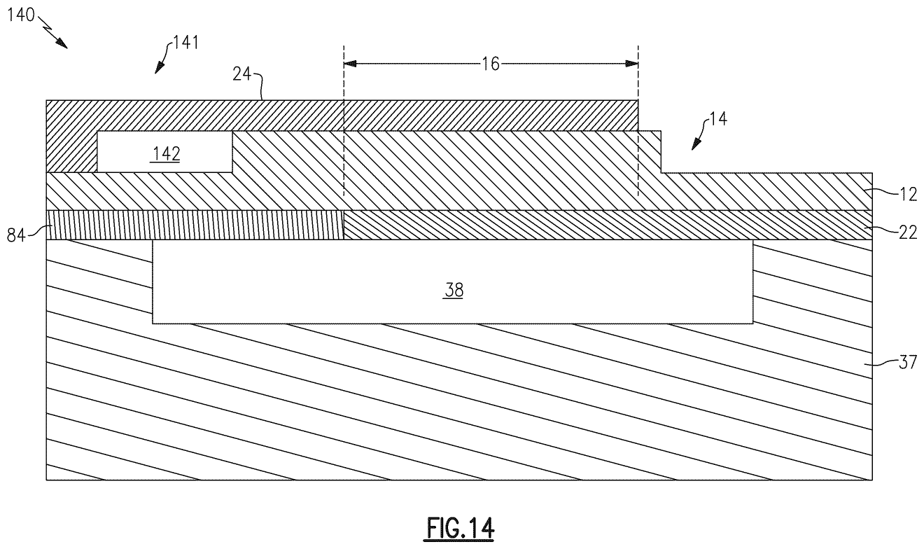

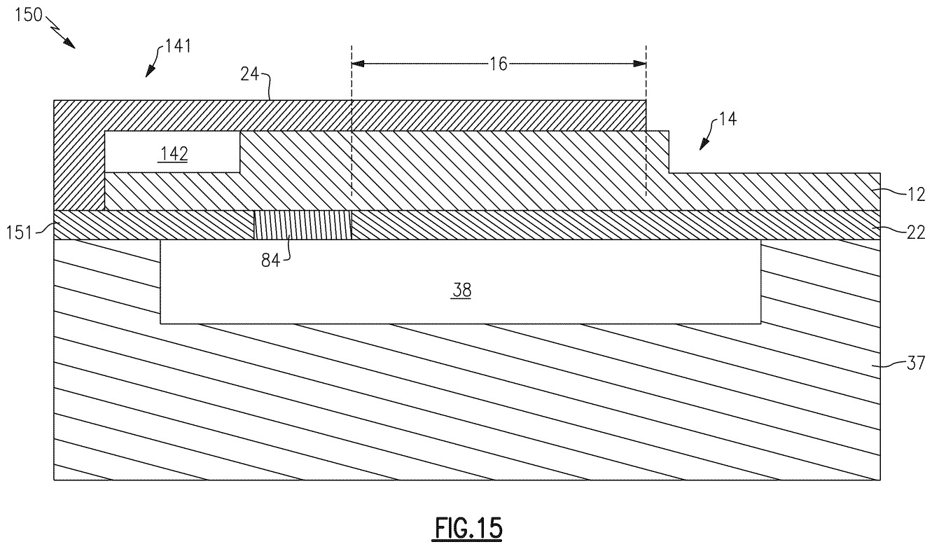

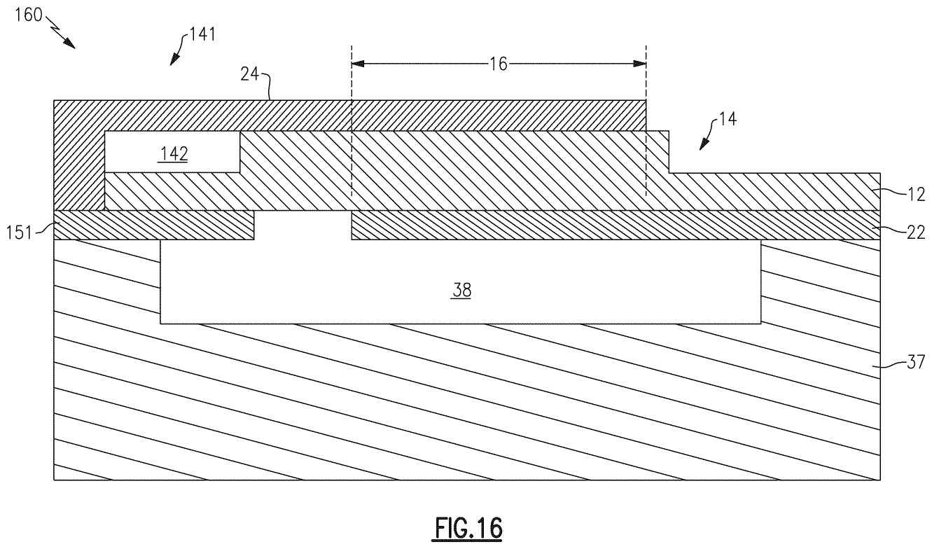

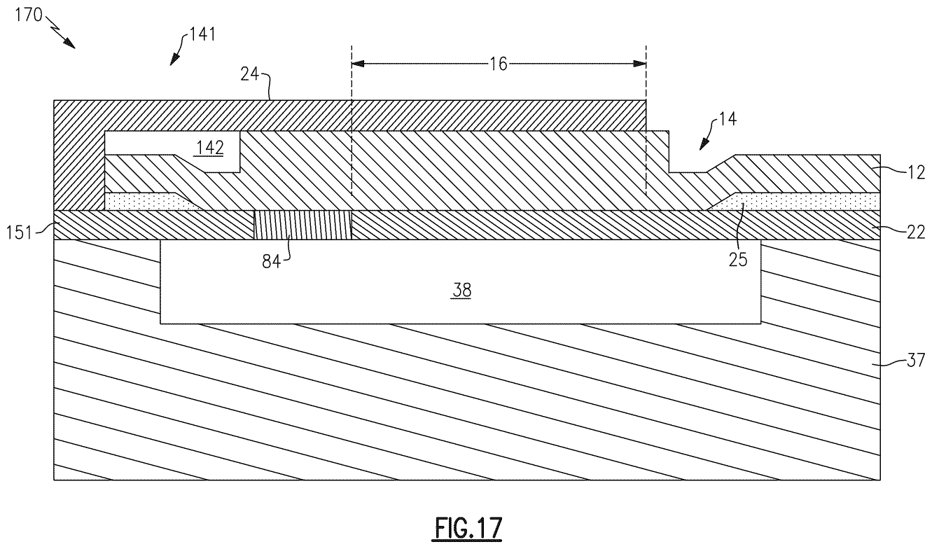

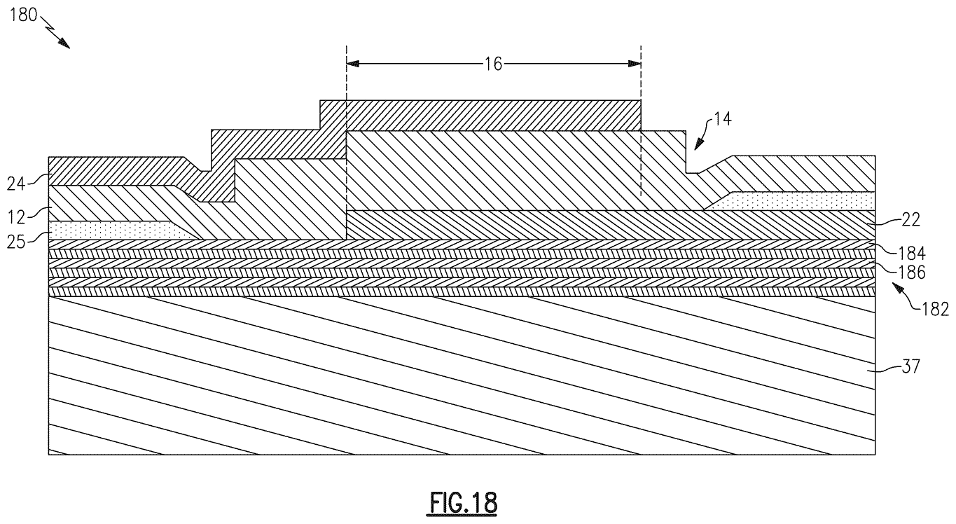

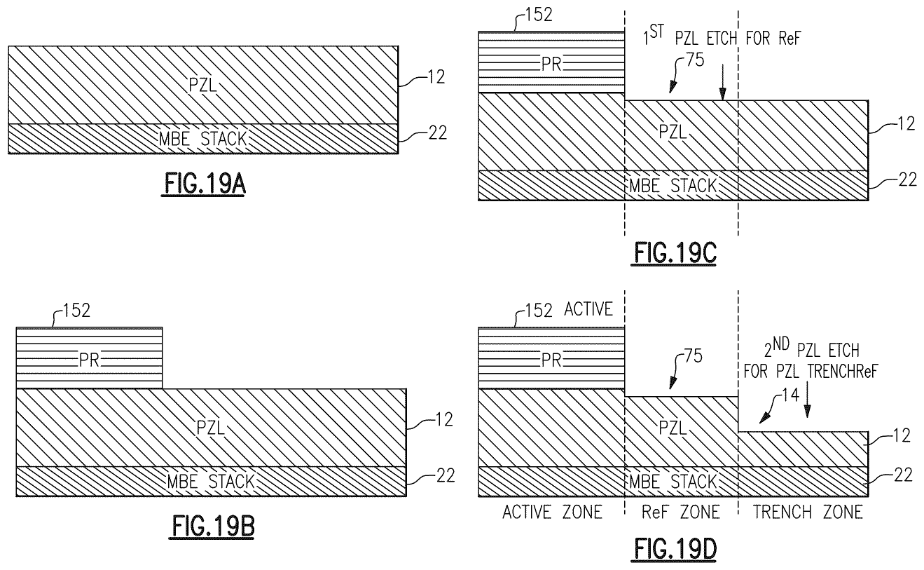

FIGS. 19A, 19B, 19C, and 19D are cross-sectional diagrams of a BAW device during a method of manufacturing where a recess is formed by etching a piezoelectric layer according to an embodiment. Referring to FIG. 19A, a BAW device structure is provided with a piezoelectric layer 12 over a first electrode 22. The piezoelectric layer 12 can be formed with a generally uniform thickness.

A photoresist 152 can be formed over a portion of the piezoelectric layer 12. FIG. 19B illustrates a BAW device structure with the photoresist 152. The photoresist 152 can be over what will become the active region of the BAW device structure after manufacturing. The photoresist 152 can be over any other region of the BAW device structure where the piezoelectric layer 12 is not etched. For example, the photoresist 152 can be over any other region of the BAW device structure where the BAW device after manufacture will have the same thickness of the piezoelectric layer 12 as the active region.

FIG. 19C illustrates the BAW device structure after a first etch. A first etch can reduce a thickness of the piezoelectric layer 12 where the piezoelectric layer 12 is not covered by the photoresist 152. The first etch can reduce the thickness of the piezoelectric layer 12 by an amount to from a recessed frame structure 75.

FIG. 19D illustrates the BAW device structure after a second etch. The second etch can create the recess 14. The first etch and the second etch can together remove at least 50% of the thickness of the piezoelectric layer 12 in certain application. In such applications, the piezoelectric layer 12 in the active region can be at least twice as thick as in the recessed region after manufacture. Between the cross-sections in FIGS. 19C and 19D, a second photoresist can be formed to cover the piezoelectric layer 12 in the recessed frame region. The second photoresist can maintain the thickness of the piezoelectric layer 12 in the recessed frame region while piezoelectric material in the recessed region is etched to create the recess 14. Then the second photoresist can be removed to arrive at the BAW device structure shown in FIG. 19D with a recessed frame structure 75 and a recess 14.

After forming the recess 14, the photoresist 152 can be removed. One or more other layers and/or structures of one or more BAW devices disclosed herein can be formed over the piezoelectric layer 12 after the recess 14 is formed. For example, a second electrode can be formed over the piezoelectric layer 12. One or more passivation layers can be formed over the second electrode. One or more raised frame structures can be formed. One or more recessed frame structures can be formed. The BAW device can be electrically connected to one or more other BAW devices of an acoustic wave filter during the manufacturing process.

While the method of manufacture corresponding to FIGS. 19A to 19D involves two etches, a recess in a piezoelectric layer can be etched with a single etch in some other applications. The piezoelectric layer can be etched three or more times to create two or more piezoelectric layer thicknesses in some applications.

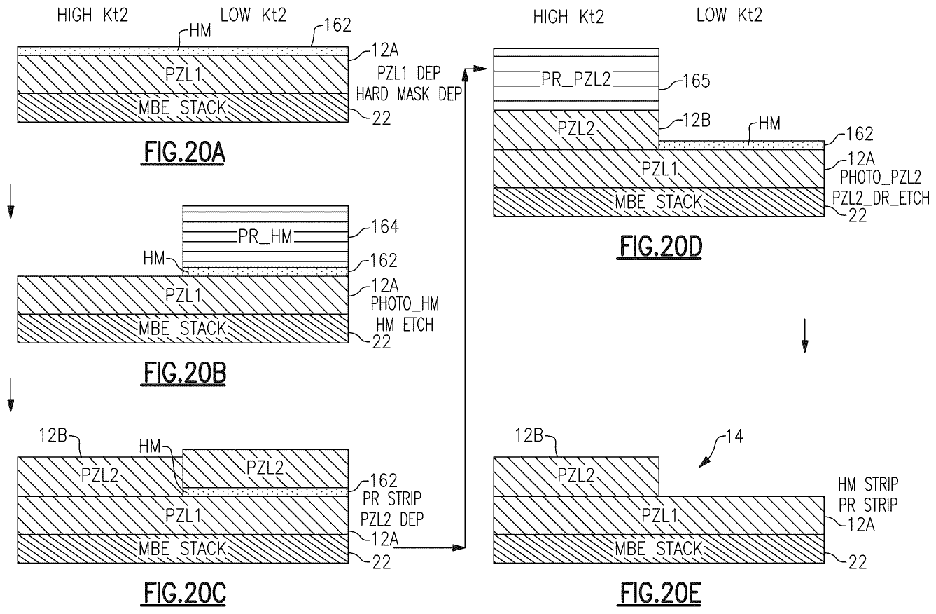

FIGS. 20A, 20B, 20C, 20D, and 20E are cross-sectional diagrams of a BAW device during manufacturing where a piezoelectric layer 12 is selectively formed with different thicknesses in different regions according to an embodiment.

A first layer of piezoelectric material 12A can be deposited over a first electrode 22. A hard mask 162 can be deposited over the first layer of piezoelectric material 12A. Referring to FIG. 20A, a BAW device structure is shown with the hard mask 162 over the layer of piezoelectric material 12A.

As shown in FIG. 20B, a photoresist hard mask 164 can be used to pattern the hard mask 162. This can involve etching the portion of the hard mask 162 that is free from the photoresist hard mask 164. The photoresist hard mask 164 can be removed. Then a second layer of piezoelectric material 12B can be formed over the first layer of piezoelectric material 12A and the hard mask 162. FIG. 20C illustrates the BAW device structure after this formation of the second layer of piezoelectric material 12B.

FIG. 20D illustrates a photoresist 165 over the part of the second layer of piezoelectric material 12B that is in physical contact with the first layer of piezoelectric material 12A and that is not over the hard mask 162. The second layer of piezoelectric material 12B that is not covered by the photoresist 165 can be removed by etching. FIG. 20D shows the hard mask 162 free from the second layer of piezoelectric material 12B.

The hard mask 162 and the photoresist 165 can then be removed to arrive at the BAW device structure shown in FIG. 20E. The recess 14 is formed by selective piezoelectric material growth and removal in the process corresponding to the cross-sectional diagrams of FIGS. 20A to 20E.

After forming the recess 14, one or more other layers and/or structures of one or more BAW devices disclosed herein can be formed over the piezoelectric layer 12. For example, a second electrode can be formed over the piezoelectric layer 12. One or more passivation layers can be formed over the second electrode. One or more frame structures can be formed, such as one or more raised frame layers and/or one or more recessed frame structures. The BAW device can be electrically connected to one or more other BAW devices of an acoustic wave filter during the manufacturing process.

While the method of manufacture corresponding to FIGS. 20A to 20E involves forming a piezoelectric layer 12 with two different thicknesses, a piezoelectric layer with three or more different thicknesses can be formed by similar processing operations in some other applications.

Any suitable principles and advantages of the method discussed with reference to FIGS. 19A to 19D can be combined with any suitable principles and advantage of the method discussed with reference to FIGS. 20A to 20E.

Applications for BAW Device with Piezoelectric Layer Having Recess

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators in a variety of applications, such as but not limited to electronic timing products.

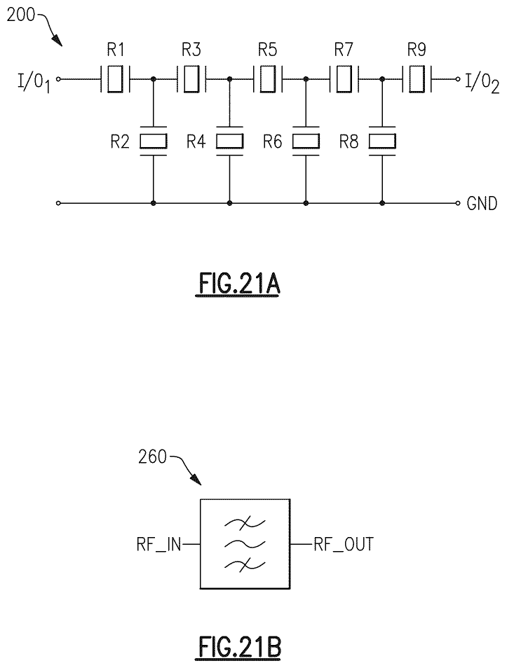

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 21A.

FIG. 21A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 200 can include a BAW resonator including a piezoelectric layer with a recess in accordance with any suitable principles and advantages disclosed herein. All acoustic resonators of the ladder filter 200 can include a BAW resonator including a piezoelectric layer with a recess in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes an acoustic wave resonator in accordance with any suitable principles and advantages disclosed herein can be arranged to filter any other suitable radio frequency signal, such as one or more of a wireless local area network signal (e.g., a Wi-Fi signal), a wireless personal area network signal (e.g., a Bluetooth signal and/or a Zigbee signal), a wireless metropolitan area network signal (e.g., a WiMAX signal), a global positioning system (GPS) signal, or the like. In certain applications, a filter that includes an acoustic wave resonator in accordance with any suitable principles and advantages disclosed herein can a bandpass filter configured to filter a radio frequency signal having a frequency in a range from 3.5 GHz to 7.125 GHZ.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 21B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

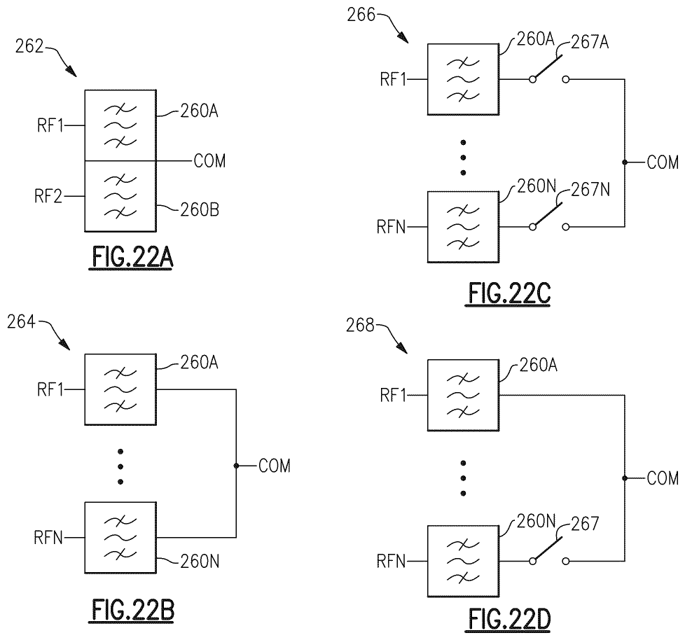

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 22A to 22D. Any suitable principles and advantages of these multiplexers can be implemented together with each other.

FIG. 22A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 22B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 22C is a schematic diagram of a multiplexer 266 that includes an acoustic wave filter according to an embodiment. The multiplexer 266 is like the multiplexer 264 of FIG. 22B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 22D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

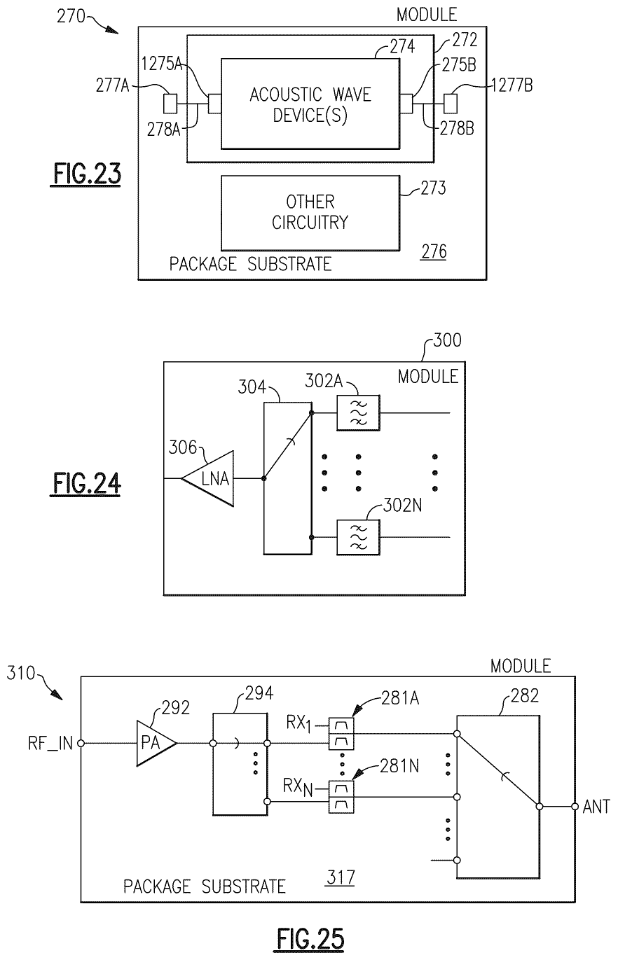

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 23, 24, and 25 are schematic block diagrams of illustrative packaged modules according to certain embodiments. Any suitable combination of features of these packaged modules can be implemented with each other.

FIG. 23 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 23 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 23. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 24 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 25 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 25 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 25 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

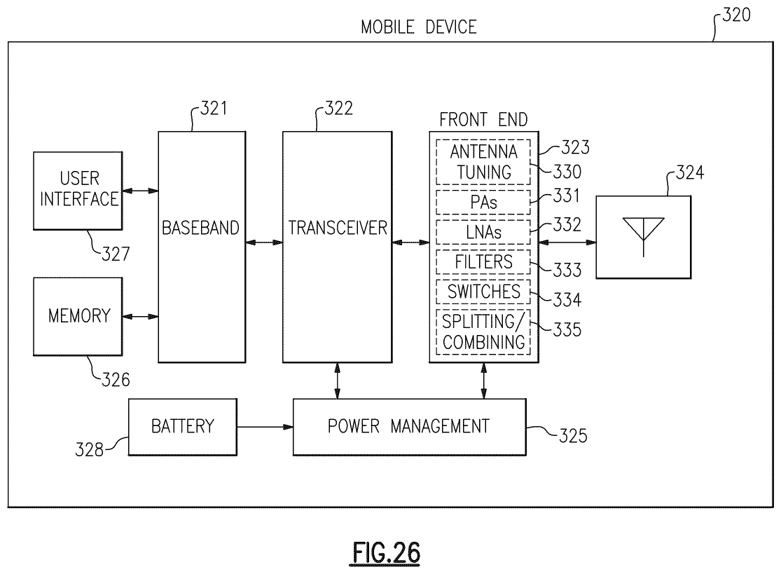

The BAW devices disclosed herein can be implemented in wireless communication devices. FIG. 26 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 26 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 26, the baseband system 321 is coupled to the memory 326 of facilitate operation of the wireless communication device 320.

The memory 326 can be used for a wide variety of purposes, such as storing data and/or instructions to facilitate the operation of the wireless communication device 320 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 26, the power management system 325 receives a battery voltage from the battery 328. The battery 328 can be any suitable battery for use in the wireless communication device 320, including, for example, a lithium-ion battery.

### TERMINOLOGY AND CONCLUSION

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks, elements, layers, or other structures are presented in a given arrangement, alternative embodiments may perform similar functionalities with different components and/or circuit topologies, and some blocks may be deleted, moved, added, subdivided, combined, and/or modified. Each of these blocks, elements, layers, or other structures may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having an active region, the bulk acoustic wave device comprising:
an acoustic reflector;
electrodes including a first electrode and a second electrode;
a piezoelectric layer having a surface facing the acoustic reflector that is flat (a) over an entirety of the active region and (b) beyond the first electrode over the acoustic reflector, the first electrode and the second electrode overlapping and being on opposing sides of the piezoelectric layer in the active region, and the first electrode positioned between the piezoelectric layer and the acoustic reflector in the active region; and
a frame structure over the acoustic reflector.

2. The bulk acoustic wave device of claim 1 wherein the frame structure is outside of the active region.

3. The bulk acoustic wave device of claim 1 wherein the surface of the piezoelectric layer facing the acoustic reflector is flat over an entirety of the acoustic reflector.

4. The bulk acoustic wave device of claim 1 further comprising a dielectric layer positioned between the piezoelectric layer and the acoustic reflector outside of the active region, the dielectric layer positioned laterally from the first electrode.

5. The bulk acoustic wave device of claim 1 wherein the frame structure includes a raised frame layer positioned on a same side of the piezoelectric layer as the first electrode.

6. The bulk acoustic wave device of claim 1 wherein the frame structure includes a raised frame layer positioned on a same side of the piezoelectric layer as the second electrode.

7. The bulk acoustic wave device of claim 1 wherein the frame structure includes a first raised frame layer positioned on a same side of the piezoelectric layer as the first electrode, and a second raised frame layer positioned on a same side of the piezoelectric layer as the second electrode.

8. The bulk acoustic wave device of claim 1 wherein the piezoelectric layer includes a recessed frame structure.

9. The bulk acoustic wave device of claim 1 further comprising a suspended frame structure.

10. The bulk acoustic wave device of claim 9 further comprising metal shorted to the suspended frame structure, the metal being on an opposite side of the piezoelectric layer than the suspended frame structure.

11. The bulk acoustic wave device of claim 9 further comprising a dielectric layer overlapping the suspended frame structure and positioned on an opposite side of the piezoelectric layer than the suspended frame structure, the dielectric layer positioned laterally from the first electrode.

12. The bulk acoustic wave device of claim 1 wherein the piezoelectric layer has a recess over the acoustic reflector and outside of the active region.

13. The bulk acoustic wave device of claim 1 wherein the acoustic reflector is an air cavity.

14. A bulk acoustic wave device having an active region, the bulk acoustic wave device comprising:
an acoustic reflector;
electrodes including a first electrode and a second electrode; and
a piezoelectric layer having a recess outside of the active region, the first electrode positioned between the piezoelectric layer and the acoustic reflector in the active region, the piezoelectric layer having a surface facing the acoustic reflector that is planar (a) over an entirety of the active region and (b) beyond the first electrode over the acoustic reflector, the first electrode and the second electrode overlapping and being on opposing sides of the piezoelectric layer in the active region.

15. The bulk acoustic wave device of claim 14 wherein the surface of the piezoelectric layer facing the acoustic reflector is planar over an entirety of the acoustic reflector.

16. The bulk acoustic wave device of claim 14 further comprising a dielectric layer positioned between the piezoelectric layer and the acoustic reflector outside of the active region, the dielectric layer positioned laterally from the first electrode.

17. The bulk acoustic wave device of claim 14 further comprising a frame structure outside of the active region and over the acoustic reflector.

18. The bulk acoustic wave device of claim 14 wherein the piezoelectric layer includes a recessed frame structure.

19. The bulk acoustic wave device of claim 14 further comprising a suspended frame structure.

20. An acoustic wave filter for filtering a radio frequency signal, the acoustic wave filter comprising:
a bulk acoustic wave resonator including an acoustic reflector; electrodes including a first electrode and a second electrode; a piezoelectric layer having a surface facing the acoustic reflector that is flat (a) over an entirety of an active region of the bulk acoustic wave resonator and (b) beyond the first electrode over the acoustic reflector, the first electrode and the second electrode overlapping and being on opposing sides of the piezoelectric layer in the active region, and the first electrode positioned between the piezoelectric layer and the acoustic reflector in the active region; and a frame structure over the acoustic reflector; and
a plurality of additional acoustic wave resonators, the bulk acoustic wave resonator and the plurality of additional acoustic wave resonators configured to filter the radio frequency signal.
